(19) United States
(12) Patent Application Publication
(10) Pub. No.: US 2016/0105999 A1
(43) Pub. Date: Apr. 14, 2016

(54) COOLING DEVICE AND COOLING FIN

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: XIN HE, Wuhan (CN); JIN-BIAO JI, Wuhan (CN); ZHI-JIANG YAO, Wuhan (CN)

(21) Appl. No.: 14/526,097

(22) Filed: Oct. 28, 2014

(30) Foreign Application Priority Data
Oct. 14, 2014 (CN) 201410540854.9

(51) Int. Cl. H05K 7/20

(52) U.S. Cl. CPC H05K 7/20336

(57) ABSTRACT

A cooling device includes a cooler. The cooler includes a base, a plurality of cooling fins secured to the base, and a heat pipe inserting through the cooling fins. Each cooling fin includes a fin body and a pressed portion extending from the fin body. The fin body includes a hole area, which defines a receiving hole. A portion of the heat pipe extends through the receiving hole; the pressed portion includes at least one guiding portion, which is configured to guide air to flow towards the hole area from the fin body.

### FIELD

The subject matter herein generally relates to cooling fins and a cooling device with the cooling fins.

### BACKGROUND

A cooling device is generally used in an electronic device to cool the electronic device. Generally, the cooling device includes a plurality of cooling fins and a heat pipe inserting through the cooling fins.

### BRIEF DESCRIPTION OF THE DRAWINGS

Implementations of the present technology will now be described, by way of example only, with reference to the attached figures.

FIG. 1 is an exploded, isometric view of an embodiment of a cooling device.

FIG. 2 is an isometric view of a cooling fin of the cooling device of FIG. 1.

FIG. 3 is a partially assembled, isometric view of the cooling device of FIG. 1.

FIG. 4 is an assembled, isometric view of the cooling device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure describes a foot stool assembly including a foot stool, a foot pad, a grasping member, and a fastener. The foot pad includes a mounting plate. The fastener secures the mounting plate and the grasping member to the foot stool. The mounting plate is located between the foot stool and the grasping member, preventing the foot pad from coming off the foot stool.

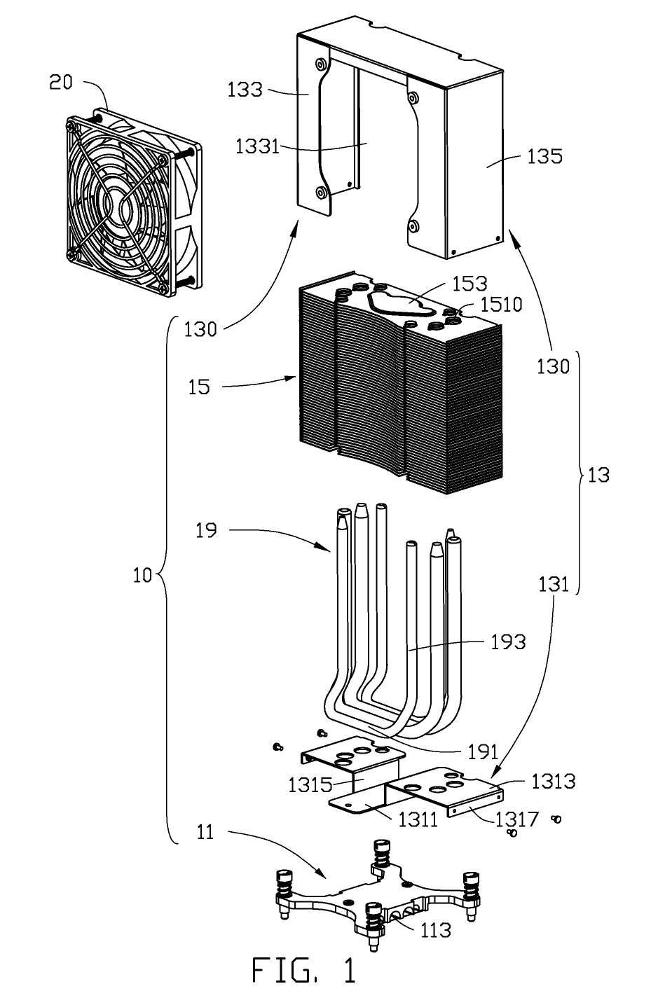

FIG. 1 illustrates a cooling device in accordance with an embodiment. The cooling device includes a cooler 10 and a fan 20 can be secured to a side of the cooler 10.

The cooler 10 includes a base 11, a housing 13, a plurality of cooling fins 15, a plurality of heat pipes 19. The base 11 defines a plurality of through holes 113 for the heat pipes 19 inserting through. A bottom surface of the base 11 can be contacted to a heating component (not shown).

The housing 13 includes a bottom plate 131 and a body 130 can be secured to the bottom plate 131. The bottom plate 131 includes a mounting piece 1311 and two holding pieces 1313. The mounting piece 1311 can be secured to the base 11. Each holding piece 1313 is connected to the mounting piece 1311 via a connecting piece 1315. In at least one embodiment, the holding pieces 1313 are coplanar with each other, and each holding piece 1313 is substantially parallel to the mounting piece 1311. The holding pieces 1313 are configured to hold the cooling fins 15. The body 130 includes a rear plate 133 and two side plates 135 perpendicularly extending from the rear plate 133. The rear plate 133 defines an air inlet 1331. Each holding piece 1313 can be secured to the side plate 135 via a flange 1317.

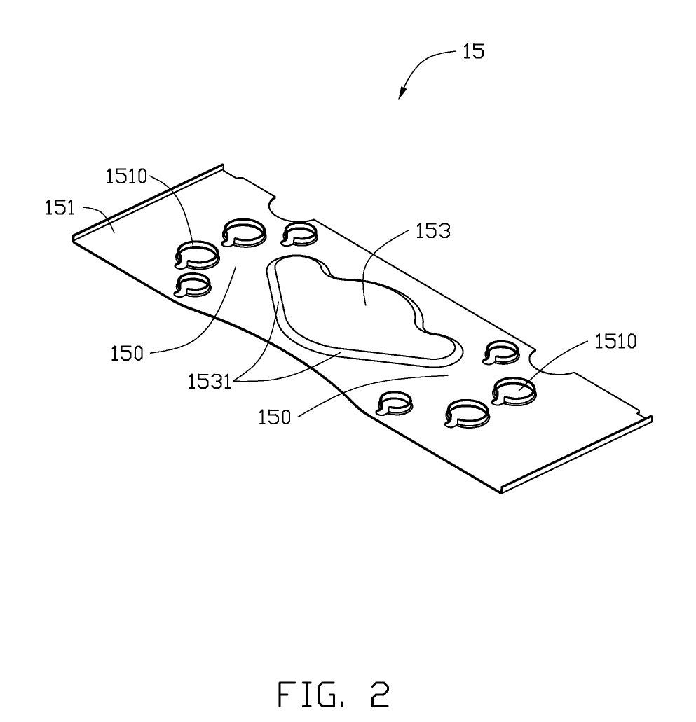

FIG. 2 illustrates that each cooling fin 15 includes a fin body 151 and a pressed portion 153 extending from the fin body 151. The pressed portion 153 includes two guiding portions 1531. In at least one embodiment, each guiding portion 1531 is flat and substantially perpendicular to the fin body 151, and the two guiding portions 1531 are formed a “V” shaped. Each hole area 150 is outside of one of the two guiding portions 1531. The guiding portion 1531 extends towards at least one receiving hole 1510. An angle is defined between an extending direction of each guiding portion 1531 and an air flowing direction. In at least one embodiment, the angle is an obtuse angle. A height of the pressed portion 153 is smaller than a distance between adjacent two cooling fins 15. The pressed portion 153 has an outer surface, which is substantially parallel to the fin body 151. A distance between the outer surface and the fin body is smaller than the distance between adjacent two cooling fins 15. In other embodiment, each guiding portion 1531 is curved to also guide the air to flow to the outer surface.

FIG. 1 illustrates that each heat pipe 19 includes a first body 191 and two second bodies 193 connected to the first body 191. Each heat pipe 19 is substantially a “U” shaped. The first body 191 is located between the two second bodies 193.

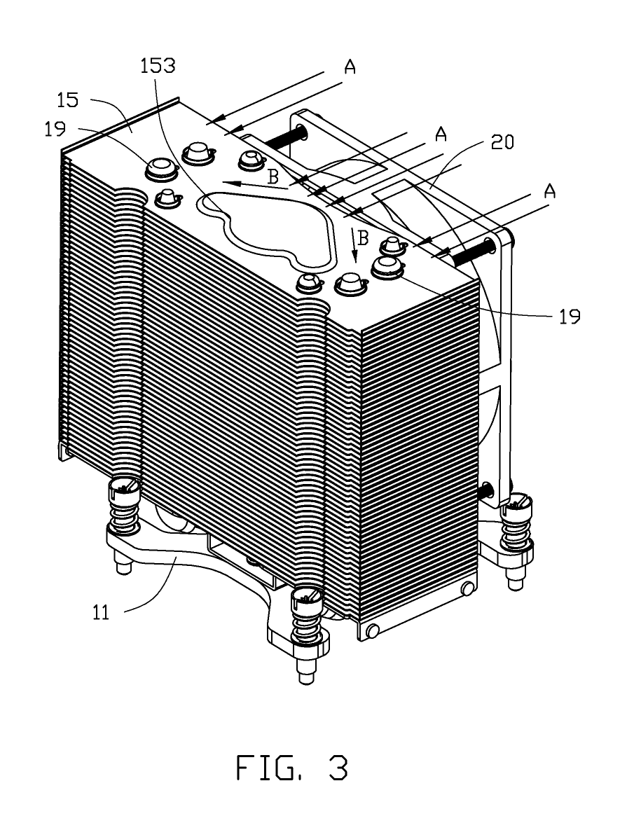

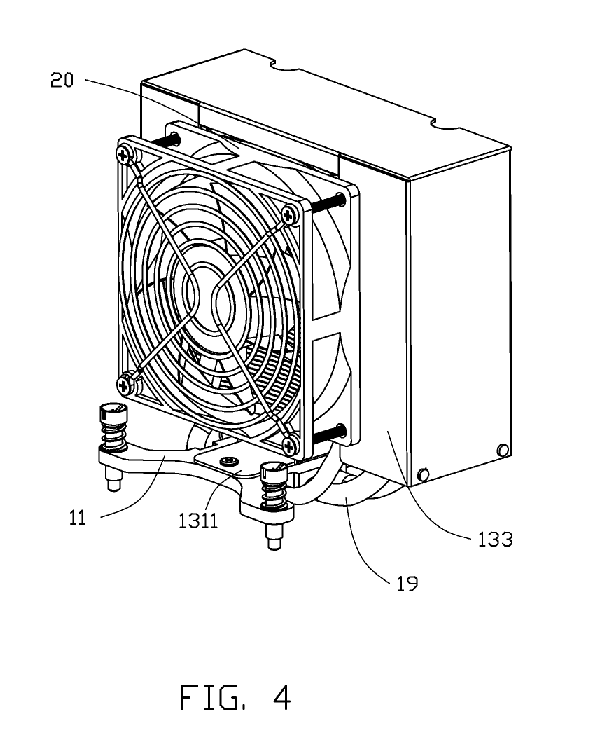

FIGS. 3 and 4 illustrate that in assembly, the mounting piece 1311 is secured to the base 11. Each holding piece 1313 is secured to the side plate 135 via the flange 1317. The cooling fins 15 are located in the housing 13 and placed on the holding pieces 1313. The first body 191 is inserted through the through hole 113. Each second body 193 is inserted through a corresponding receiving hole 1510. The fan 20 is secured to the rear plate 133 and aligned with the air inlet 1331.

In use, heat generated from the heating component is transferred to the heat pipe 19 via the base 11. Because the heat is transferred to the cooling fins 15 through the heat pipe 19, the heat in the hole area 150 is greater than other areas of the cooling fins 15. The fan 20 is operated to guide air to flow in the cooling fins 15 in a direction A. The guiding portions 1531 guides the air to flow towards the hole area 150 in a direction B, to increase air flow in the hole area 150. In at least one embodiment, the direction A is substantially parallel to the side plate 135, and an acute angle is defined between the direction B and the direction A.

The embodiments shown and described above are only examples. Many details are often found in the art such as the other features of a cooling device and cooling fin. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A cooling device comprising:
a cooler comprising a base;
a plurality of cooling fins secured to the base, each cooling fin comprising a fin body and a pressed portion extending therefrom, the fin body comprising a hole area which defines at least one receiving hole, and a heat pipe inserting through the cooling fins; and
at least one heat pipe passing through the receiving hole of each of the plurality cooling fins,
wherein the pressed portion comprises at least one guiding portion configured to guide air to flow toward the hole area from the fin body.

2. The cooling device of claim 1, wherein the at least one guiding portion extends towards the hole area.

3. The cooling device of claim 2, wherein an acute angle is defined between an extending direction of the at least one guiding portion and a flowing direction of the air in the fin body.

4. The cooling device of claim 1, wherein the at least one guiding portion is substantially perpendicular to the fin body.

5. The cooling device of claim 1, wherein the at least one guiding portion is curved.

6. The cooling device of claim 1, wherein the at least one guiding portion comprises two guiding portions, the hole area is outside of the two guiding portions, and the two guiding portions are substantially “V” shaped.

7. The cooling device of claim 2, wherein the cooler further comprises a housing configured to receive the cooling fins, the housing comprises a bottom plate and a body secured to the bottom plate, the bottom plate is secured to the base, and the cooling fins are held on the bottom plate.

8. The cooling device of claim 7, wherein the bottom plate comprises a mounting piece and a holding piece substantially parallel to the mounting piece, the mounting piece is secured to the base, and the holding piece is secured to the body and holds the cooling fins.

9. The cooling device of claim 7, further comprising a fan, wherein the body comprises a rear plate and a side plate substantially perpendicular to the rear plate, the fan is secured to the rear plate, the fin body is substantially perpendicular to the rear plate and the side plate, and the flowing direction of the air in the fin body is substantially parallel to the side plate.

10. A cooling device comprising:
a cooler comprising a base, a plurality of cooling fins secured to the base, and at least one heat pipe inserting through the cooling fins; and
a fan secured to the cooler;
wherein each cooling fin comprises a fin body and a pressed portion extending therefrom;
the fin body comprises a hole area which defines at least one receiving hole, and the heat pipe extends through the receiving hole of each of the plurality cooling fins; the pressed portion comprises at least one guiding portion; the fan is operable to flow air in the fin body, and an acute angle is defined between an extending direction of the at least one guiding portion and a flowing direction of the air in the fin body, guiding air to flow towards the hole area from the fin body.

11. The cooling device of claim 10, wherein the at least one guiding portion extends towards the hole area.

12. The cooling device of claim 10, wherein the at least one guiding portion is substantially perpendicular to the fin body.

13. The cooling device of claim 10, wherein the at least one guiding portion is curved.

14. The cooling device of claim 10, wherein the at least one guiding portion comprises two guiding portions, the hole area is outside of the two guiding portions, and the two guiding portions are substantially “V” shaped.

15. The cooling device of claim 10, wherein the cooler further comprises a housing configured to receive the cooling fins, the housing comprises a bottom plate and a body secured to the bottom plate, the bottom plate is secured to the base, and the cooling fins are held on the bottom plate.

16. The cooling device of claim 15, wherein the bottom plate comprises a mounting piece and a holding piece substantially parallel to the mounting piece, the mounting piece is secured to the base, and the holding piece is secured to the body and holds the cooling fins.

17. The cooling device of claim 10, wherein the body comprises a rear plate and a side plate substantially perpendicular to the rear plate, the fan is secured to the rear plate, the fin body is substantially perpendicular to the rear plate and the side plate, and the flowing direction of the air in the fin body is substantially parallel to the side plate.

18. A cooling fin comprising:
a fin body comprising a hole area, which defining a receiving hole; and
a pressed portion extending from the fin body;
wherein the receiving hole is configured for a heat pipe passing through; and the pressed portion comprises at least one guiding portion, which is configured to guide air to flow towards the hole area from the fin body.

19. The cooling fin of claim 18, wherein the at least one guiding portion extends towards the hole area, and an acute angle is defined between an extending direction of the at least one guiding portion and a flowing direction of the air in the fin body.

20. The cooling fin of claim 18, wherein the at least one guiding portion is substantially perpendicular to the fin body.
